(19) United States
(12) Patent Application Publication
(10) Pub. No.: US 2012/0064370 A1
(43) Pub. Date: Mar. 15, 2012

(54) ALUMINUM ALLOY REFLECTIVE FILM, REFLECTIVE FILM LAMINATE, AUTOMOTIVE LIGHTING DEVICE, ILLUMINATION DEVICE, AND ALUMINUM ALLOY SPUTTERING TARGET

(75) Inventors: Shinichi Tanifuji, Hyogo (JP); Toshiki Sato, Hyogo (JP); Yoshinori Ito, Hyogo (JP); Takayuki Tsubota, Hyogo (JP); Jun Suzuki, Hyogo (JP); Nobuhiro Kobayashi, Hyogo (JP)

(73) Assignee: Kabushiki Kaisha Kobe Seiko Sho (Kobe Steel, Ltd.), Kobe-shi (JP)

(21) Appl. No.: 13/320,673

(22) PCT Filed: Jun. 15, 2010
(86) PCT No.: PCT/JP10/60146

§ 371 Date: Nov. 15, 2011

(30) Foreign Application Priority Data
Jun. 15, 2009 (JP) 2009-142389

(51) Int. Cl. B32B 3/00; C23C 14/34; C23C 14/14

(52) U.S. Cl. 428/687; 428/141; 204/298.13

(57) ABSTRACT

Disclosed is an Al alloy reflective film which has a higher reflectance than that of pure Al films when produced by sputtering, excels in alkali resistance, acid resistance, and moisture resistance, and therefore less suffers from the reduction in reflectance even when a protective coating is not applied. Specifically disclosed is an Al alloy reflective film which contains at least one element selected from Sc, Y, La, Gd, Tb, and Lu in a total amount of from 0.4 to 2.5 atomic percent, with the remainder being Al and inevitable impurities. The Al alloy reflective film has a film surface roughness of 4 nm or less as measured with an atomic force microscope. Also disclosed are an automotive lighting device and an illumination device each provided with the reflective film. Further disclosed is an Al alloy sputtering target for use in the formation of the reflective film.

### TECHNICAL FIELD

The present invention relates to aluminum alloy reflective films, reflective film laminates, automotive lighting devices, illumination devices, and aluminum alloy sputtering targets.

### BACKGROUND ART

Pure aluminum films are used as reflective films typically for automotive lighting devices and illumination devices because they have high reflectances of from 88% to 90%, higher than those of other metal materials.

However, pure aluminum films deposited by some techniques under some conditions may enlarge film surface roughness and may thereby undergo reduction in reflectance. In this connection, sputtering is mainstream for the deposition of a thin film because this technique allows relatively easy control of film thickness in nanometers. When a pure aluminum film is deposited by the sputtering, aluminum atoms emitted from a pure aluminum sputtering target have high energy, and aluminum atoms adsorbed on a substrate thereby easily diffuse or migrate on the surface. Aluminum nuclei are therefore formed in a small number density during the initial process of film deposition, and this causes aluminum nuclei to grow and form coarse aluminum grains, and, when the grains lie adjacent to each other to form a continuous film, the resulting pure aluminum film has a rough surface. Such a pure aluminum film deposited by sputtering often has a reflectance of about 85%, because the film shows a decreased reflectance with an increasing roughness of film surface, though the reflectance may vary depending on the deposition conditions.

In addition, pure aluminum is an amphoteric metal and thereby has poor resistance to corrosion by acids and alkalis. A reflective film, particularly when used for an automotive lighting device, requires durability to alkalis. For this purpose, a pure aluminum film is not usable as intact as a reflective film, because of its insufficient alkali resistance, and is used as a laminate including the pure aluminum film and, formed thereon, a coating typically of an alkali-resistant paint to thereby have improved alkali resistance.

A transparent coating is used as the protective coating typically of a paint, but this may reduce the reflectance of the pure aluminum film. If the protective coating bears defects such as pinholes, corrosion of the pure aluminum film occurs from the defects, resulting in gradual decrease in reflectance. The problem of pinholes may be improved by increasing the thickness of the protective coating, but this causes reduction in reflectance, reduction in productivity, and increase in cost, thus being not so effective.

In a laser reflective film use, there is known an aluminum alloy thin film which has satisfactory corrosion resistance and a high reflectance and contains any of transition metal elements of Group IIa, Group IVa, Group Va, Group VIa, Group VIIa, and Group VIII of the periodic table (see Patent Literature (PTL) 1). The literature mentions that this aluminum alloy forms a chemically stable passive state and thereby shows satisfactory corrosion resistance in acidic to neutral regions. However, the technique disclosed in the literature never considers the corrosion resistance of the reflective film in an alkaline region where the passive film is dissolved to cause corrosion to proceed. It is therefore unknown that the aluminum alloy thin film containing the transition metal element is usable for automotive lighting devices where alkali resistance is required. Even when a protective coating is formed on the aluminum alloy thin film, defects, if included in the protective coating, may cause corrosion of aluminum, resulting in reduction in reflectance.

Independently, there has been proposed an aluminum alloy reflective film containing aluminum and, added thereto, magnesium (Mg) in a content of from 0.1 to 15 percent by mass to improve corrosion resistance (see PTL 2). Magnesium (Mg) forms a transparent oxide film on the surface and thereby also improves alkali corrosion resistance, but fails to give a sufficiently improved alkali resistance when added in a content within the above-specified range. In addition, Mg is gradually oxidized when exposed to a hot and humid environment, and this causes the aluminum alloy reflective film to become transparent. Accordingly, when the Mg-containing aluminum alloy reflective film bearing a protective film is exposed to a hot and humid environment and if the protective coating typically has defects, the corrosion and oxidation of Al occur from the defects, and this may reduce the reflectance of the reflective film.

There has been proposed an aluminum alloy reflective film (see PTL 3) which has improved resistance to a hot and humid environment, by adding a rare-earth element to the alloy system described in PTL 2. This aluminum alloy reflective film contains Mg in a content of from 0.1 to 15 percent by mass and a rare-earth element in a content of from 0.1 to 5 percent by mass. The aluminum alloy reflective film has improved corrosion resistance in a hot and humid environment because of the addition of a rare-earth element, but has alkali resistance improved little, because the alloy thereof is not designed from the viewpoint of improving alkali corrosion resistance. When the aluminum alloy reflective film is placed in an alkaline environment and if the protective coating typically has defects, the defects may cause corrosion of aluminum and/or discoloration of the aluminum film due to enrichment of the added rare-earth element, and this may cause the reflective film to undergo reduction in reflectance.

### CITATION LIST

### Patent Literature

PTL 1: Japanese Unexamined Patent Application Publication (JP-A) No. H07-301705
PTL 2: Japanese Unexamined Patent Application Publication (JP-A) No. 2007-72427
PTL 3: Japanese Unexamined Patent Application Publication (JP-A) No. 2007-70721

### SUMMARY OF INVENTION

### Technical Problem

The present invention has been made in consideration of these circumstances, and an object thereof is to provide such an aluminum alloy reflective film as follows. The aluminum alloy reflective film, when deposited by sputtering, has a reflectance higher than that of a pure aluminum film, excels in alkali resistance (resistance to corrosion by alkalis), acid resistance (resistance to corrosion by acids), and moisture resistance (resistance to a hot and humid environment), and is thereby resistant to reduction in reflectance over a long time even without a protective coating. In addition, when a protective coating is provided, the aluminum alloy reflective film less suffers from reduction in reflectance even when the protective coating bears defects. Another object of the present invention is to provide a reflective film laminate, an automotive lighting device, and an illumination device including the aluminum alloy reflective film; and an aluminum alloy sputtering target capable of forming the aluminum alloy reflective film.

### Solution to Problem

After intensive investigations to achieve the objects, the present inventors have made the present invention. The present invention achieves the objects.

The present invention thus made and achieving the objects relates to an aluminum alloy reflective film, a reflective film laminate, an automotive lighting device, an illumination device, and an aluminum alloy sputtering target and provides an aluminum alloy reflective film according to claim 1 (aluminum alloy reflective film according to First Embodiment); an automotive lighting device according to claim 2 (automotive lighting device according to Second Embodiment) and an illumination device (illumination device according to Third Embodiment) each including the aluminum alloy reflective film; a reflective film laminate according to claim 4 (reflective film laminate according to Fourth Embodiment); an automotive lighting device according to claim 5 (automotive lighting device according to Fifth Embodiment) and an illumination device (illumination device according to Sixth Embodiment) each including the reflective film laminate; and aluminum alloy sputtering targets according to claims 7 and 8 (aluminum alloy sputtering targets according to Seventh and Eighth Embodiments). These have the following configurations.

Specifically, the aluminum alloy reflective film according to claim 1 is an aluminum alloy reflective film which contains at least one element selected from the group consisting of Sc, Y, La, Gd, Tb, and Lu in a total content of from 0.4 to 2.5 atomic percent, with the remainder being Al and inevitable impurities, and which has an average roughness Ra of film surface of 4 nm or less as measured with an atomic force microscope [First Embodiment].

The automotive lighting device according to claim 2 is an automotive lighting device which includes the aluminum alloy reflective film of claim 1 as a reflective film [Second Embodiment].

The illumination device according to claim 3 is an illumination device which includes the aluminum alloy reflective film of claim 1 as a reflective film [Third Embodiment].

The reflective film laminate wan-ding to claim 4 is a reflective film laminate which includes the aluminum alloy reflective film of claim 1 and, present thereon, a plasma-enhanced polymerized film [Fourth Embodiment].

The automotive lighting device according to claim 5 is an automotive lighting device which includes the reflective film laminate of claim 4 as a reflective film laminate [Fifth Embodiment].

The illumination device according to claim 6 is an illumination device which includes the reflective film laminate of claim 4 as a reflective film laminate [Sixth Embodiment].

The aluminum alloy sputtering target according to claim 7 is an aluminum alloy sputtering target for the formation of the aluminum alloy reflective film of claim 1, which sputtering target includes at least one element selected from the group consisting of Sc, Y, La, Gd, Tb, and Lu in a total content of from 0.4 to 4.5 atomic percent, with the remainder being Al and inevitable impurities [Seventh Embodiment].

The aluminum alloy sputtering target according to claim 8 is the aluminum alloy sputtering target of claim 7 which has been prepared by spray forming [Eighth Embodiment].

### Advantageous Effects of Invention

The aluminum alloy reflective film according to the present invention, when deposited by sputtering, has a reflectance higher than that of a pure aluminum film and excels in alkali resistance (resistance to corrosion by alkalis), acid resistance (resistance to corrosion by acids), and moisture resistance (resistance to a hot and humid environment). When used as a reflective film without a protective coating provided thereon, the aluminum alloy reflective film is therefore expected to maintain, over a long time, a reflectance higher than that of a pure aluminum film deposited by sputtering. In particular, the aluminum alloy reflective film is advantageously usable as a reflective film for an automotive lighting device where durability to alkalis is required, thus being useful.

The aluminum alloy sputtering target according to the present invention enables the formation of the aluminum alloy reflective film according to the present invention.

When used in a site where the film is exposed to a more severe environment in such automotive lighting device use, a plasma-enhanced polymerized film may be formed as a protective coating on the aluminum alloy reflective film. Even if the plasma-enhanced polymerized film bears some defects, the aluminum alloy reflective film less suffers from reduction in reflectance because of high durability of the aluminum alloy reflective film in itself. The reflective film laminate according to the present invention, as having the aluminum alloy reflective film, has a high reflectance and less suffers from reduction in reflectance, thus being useful. In addition, the plasma-enhanced polymerized film for use herein not always has to be perfect as described above, and this reduces time and effort for the formation of the plasma-enhanced polymerized film. Thus, improvement in productivity and reduction in cost are expected.

The automotive lighting device and the illumination device according to the present invention includes the aluminum alloy reflective film or reflective film laminate according to the present invention, thereby have high reflectances and are resistant to reduction in reflectance.

### BRIEF DESCRIPTION OF DRAWINGS

FIG. 1 schematically illustrates how nuclei diffuse and grains grow in sputtering deposition of a pure aluminum film.

FIG. 2 schematically illustrates how nuclei diffuse and grains grow in sputtering deposition of an aluminum alloy film containing a rare-earth element such as a Sc—Lu group element.

FIG. 3 is a graph illustrating how the arithmetic average surface roughness varies depending on the content of Sc—Lu group element.

FIG. 4 is a graph illustrating how the initial visible-light reflectance varies depending on the content of Sc—Lu group element.

FIG. 5 is a view schematically illustrating a plasma chemical vapor deposition (plasma CVD) apparatus used in the preparation of a reflective film laminate (particularly in the formation of a plasma-enhanced polymerized film).

### DESCRIPTION OF EMBODIMENTS

The aluminum alloy reflective film according to the present invention contains at least one element selected from the group consisting of Sc, Y, La, Gd, Tb, and Lu in a total content of from 0.4 to 2.5 atomic percent, with the remainder being Al and inevitable impurities, and has an average roughness Ra of film surface of 4 nm or less as measured with an atomic force microscope, as is described above [First Embodiment]. The aluminum alloy reflective film, as having the specific chemical composition, has a smooth surface with an average roughness (arithmetic average roughness) Ra of 4 nm or less, less suffers from reduction in reflectance, and has a reflectance higher than that of a pure aluminum film, even when deposited by sputtering. In addition, the aluminum alloy reflective film excels in alkali resistance (resistance to corrosion by alkalis), acid resistance (resistance to corrosion by acids), and moisture resistance (resistance to a hot and humid environment). Accordingly, when used as a reflective film without a protective coating provided thereon, the aluminum alloy reflective film can maintain, over a long time, a reflectance higher than that of a pure aluminum film deposited by sputtering. Details about the aluminum alloy reflective film will be illustrated below.

The aluminum alloy reflective film according to the present invention less suffers from reduction in film reflectance and film discoloration in a moisture resistance test, an alkali resistance test, and an acid resistance test, as choosing a rare-earth element to be alloyed with aluminum from the viewpoint of improving the alkali resistance of aluminum. By specifying the content of the rare-earth element to be from 0.4 to 2.5 atomic percent, the resulting deposited aluminum alloy film can have a reflectance higher than that of a pure aluminum film deposited by sputtering.

A rare-earth element, when added to aluminum, helps the resulting aluminum alloy to have sufficiently satisfactory moisture resistance. In an acidic environment, the rare-earth element helps the aluminum alloy to have reliably and sufficiently satisfactory acid resistance, because the aluminum alloy has a less noble immersion potential than that of pure aluminum, and this prevents the dissolution of aluminum to thereby improve the acid resistance. In an alkaline environment, the rare-earth element helps the aluminum alloy to have a less noble immersion potential and, during dissolution, precipitates and concentrates as a hydroxide on the surface of the Al-rare-earth element alloy (hereinafter also referred to as Al-REM alloy), and this serves as a protective film to reduce the dissolution rate of the reflective film as a whole. However, of rare-earth elements, Eu, Sm, and Yb are less effective to reduce the dissolution rate, because these elements, when immersed in an alkali, become ions to be dissolved in the solution and do not precipitate on the surface of the Al-REM alloy. In consideration of this, rare-earth elements effective to reduce the dissolution rate are Sc, Y, La, Ce, Nd, Pr, Gd, Dy, Tb, Ho, Er, Tm, and Lu. Of these elements, preferred are Sc, Y, La, Gd, Tb, and Lu (these elements are hereinafter also referred to as Sc—Lu group elements). The Sc—Lu group elements are less colored even when precipitated as a hydroxide on the surface of the Al-REM alloy and less cause discoloration of the alloy film even after being immersed in an alkali aqueous solution. In contrast, other rare-earth elements, such as Ce, than the Sc—Lu group elements give hydroxides typically colored yellow or brown and cause discoloration when precipitate and concentrate on the surface of the Al-REM alloy. The discoloration impairs the appearance of the reflective film, thus being undesirable.

As elements to be alloyed with aluminum, preferred are Y, La, Gd, Tb, and Lu, of which La and Gd are more preferred, in consideration of the alkali resistance of the film, the appearance of the film after an alkali resistance test, and the production cost of a sputtering target for use in the deposition.

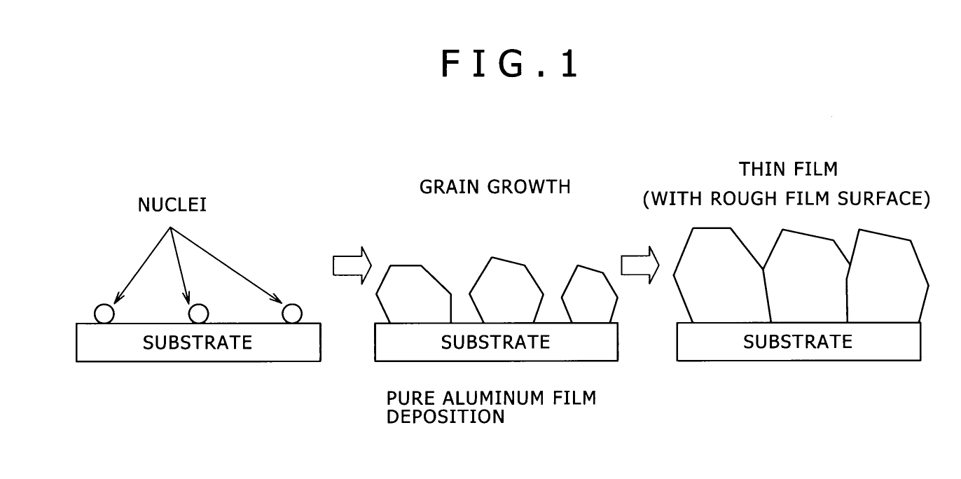

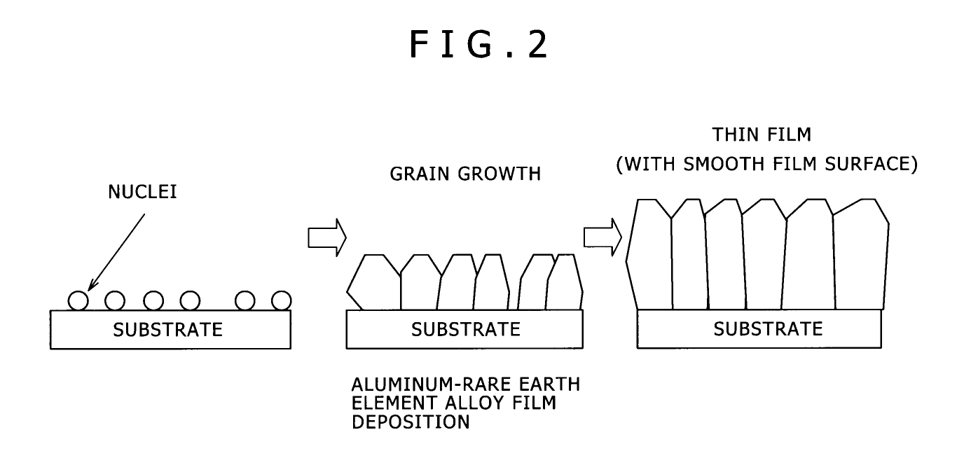

When a pure aluminum film is deposited by sputtering, the resulting film has a rough surface because of small nucleation density of aluminum and thereby fails to provide a high reflectance inherent to aluminum (FIG. 1). However, a rare-earth element such as a Sc—Lu group element, when added, less diffuses on the surface of the substrate, thereby serves as aluminum nucleation points on the substrate, and increases the nucleation density of aluminum. This is probably because, when such densely distributed nuclei grow to be crystal grains, they collide against adjacent grains after slight growth, thereby become fine crystals without grain growth in a direction along the substrate surface, and the fine crystal grains grow in the film thickness direction to give a relatively smooth surface with a small roughness (FIG. 2). This results in improved reflectance. Specifically, the aluminum alloy reflective film, even when deposited by sputtering, less suffers from reduction in reflectance and thereby has a high reflectance. However, the added rare-earth element, if having sufficient energy to diffuse on the substrate, may reduce the nucleation density of aluminum and may thereby reduce the reflectance of the reflective film. Specifically, an increased power for deposition or a decreased distance between the substrate and target may result in increase in energy of sputtered particles, and this may increase the surface roughness and reduce the reflectance. Deposition conditions should therefore be modified as appropriate according to an apparatus to be used.

However, a rare-earth element such as a Sc—Lu group element, if contained in an excessively large content, causes reduction in reflectance, because the reflectance of the aluminum alloy film itself decreases with an increasing content of the rare-earth element. The aluminum alloy reflective film preferably contains a rare-earth element such as a Sc—Lu group element in a content of from 0.4 to 2.5 atomic percent to obtain a reflectance of from 88% to 90%, equivalent to the reflectance inherent to pure aluminum. The rare-earth element, if contained in a content of less than 0.4 atomic percent, may not help crystal grains to be fine and may not help the resulting film to have an improved reflectance. The content is more preferably 0.5 atomic percent or more. In contrast, the content of the rare-earth element to be alloyed with aluminum is preferably 2.5 atomic percent or less, and more preferably 1 atomic percent or less, because if the content is more than 2.5 atomic percent, the resulting film has a reflectance of less than 88%.

Based on the above considerations, the aluminum alloy reflective film according to the present invention is specified to be an aluminum alloy reflective film containing at least one Sc—Lu group element (selected from Sc, Y, La, Gd, Tb, and Lu) in a total content of from 0.4 to 2.5 atomic percent, with the remainder being Al and inevitable impurities [First Embodiment]. As demonstrated by the above descriptions, the aluminum alloy reflective film less suffers from reduction in reflectance and thereby has a high reflectance even when deposited by sputtering. In addition, the aluminum alloy reflective film excels in alkali resistance (resistance to corrosion by alkalis), acid resistance (resistance to corrosion by acids), and moisture resistance (resistance to a hot and humid environment) and thereby less suffers from reduction in reflectance even when a protective coating formed thereon has some defects. The aluminum alloy reflective film is therefore advantageously usable as a reflective film, thus being useful.

The aluminum alloy reflective film according to the present invention has a small surface roughness even when deposited by sputtering, as is described above. Specifically, the aluminum alloy reflective film has an average roughness Ra of film surface of 4 nm or less as measured with an atomic force microscope [First Embodiment].

In an embodiment, a plasma-enhanced polymerized film is formed on the aluminum alloy reflective film according to the present invention, and the resulting laminate is used as a reflective film laminate [Fourth Embodiment]. The reflective film laminate has further satisfactory alkali resistance and maintains a high reflectance over a further longer duration, thus being desirable. In the laminate, the plasma-enhanced polymerized film preferably has a thickness of from 10 to 1000 nm. The plasma-enhanced polymerized film, if having a thickness of less than 10 nm, may not be present as a continuous film, and the formation of the plasma-enhanced polymerized film becomes meaningless. In contrast, the plasma-enhanced polymerized film, if having a thickness of more than 1000 nm, may cause reduction in reflectance. The plasma-enhanced polymerized film is preferably one formed from an organosilicon as a material. Examples of the organosilicon include hexamethyldisiloxane, hexamethyldisilazane, and triethoxysilane.

The automotive lighting device and illumination device according to embodiments [Second and Third Embodiments] of the present invention each include the aluminum alloy reflective film according to the present invention as a reflective film, as described above. The automotive lighting device and illumination device according to other embodiments [Fifth and Sixth Embodiments] each include the reflective film laminate according to Fourth Embodiment of the present invention as a reflective film laminate. The reflective film laminate includes the aluminum alloy reflective film according to the present invention. Accordingly, these automotive lighting devices and illumination devices, even when the constituent aluminum alloy reflective film is deposited by sputtering, less suffer from reduction in reflectance, thereby have a high reflectance. In addition, they excel in alkali resistance (resistance to corrosion by alkalis), acid resistance (resistance to corrosion by adds), and moisture resistance (resistance to a hot and humid environment), and less suffer from reduction in reflectance even when the protective coating has some defects, thus being useful.

The aluminum alloy sputtering target according to the present invention, as is described above, contains at least one element selected from the group consisting of Sc, Y, La, Gd, Tb, and Lu in a total content of from 0.4 to 4.5 atomic percent, with the remainder being Al and inevitable impurities [Seventh Embodiment]. The aluminum alloy sputtering target enables the formation of the aluminum alloy reflective film according to the present invention as described above. To form an aluminum alloy film having a desired composition, an aluminum alloy sputtering target having a composition different from that of the aluminum alloy film should be prepared in consideration of yield The sputtering target composition thus differs from the film composition, probably because the rare-earth element once taken into the film is re-sputtered by the action of new-coming sputtered particles, though the solid mechanism thereof still remains unknown. The elements Gd, Y, and La, which have been investigated herein, have yields decreasing in the order of Y, Gd, and La (Y>Gd>La), and this order is in correlation with the order of the atomic radii of them. This is probably because an atom with a larger atomic radius has a larger area, and this increases the probability of re-sputtering. The yield herein is determined according to the following expression Yield=[(Content of REM in Al-REM alloy film)/(Content of REM in Al-REM alloy sputtering target)]×100(%).

The aluminum alloy sputtering target may be prepared by any process without limitation, but is preferably prepared by spray forming. This is because the resulting aluminum alloy sputtering target prepared by spray forming is highly uniform in chemical composition and thereby gives an aluminum alloy reflective film having a uniform chemical composition [Eighth Embodiment].

### EXAMPLES

Some working examples according to the present invention, and comparative examples will be illustrated below. It should be noted, however, that these examples are never construed to limit the scope of the present invention, and alternations and changes as appropriate are possible within the spirit and scope of the present invention, and they are all fall in the technical scope of the present invention.

### Example 1 and Comparative Example 1

Aluminum alloy films having compositions given in Table 1 were deposited each on a glass substrate (Corning #1737) using a direct-current (DC) magnetron sputtering apparatus. How the deposition was performed will be described below.

A sputtering target serving as a sputtering target for the deposition of an aluminum alloy film was attached to an electrode in a chamber of the sputtering apparatus, and the chamber was evacuated to an inner pressure of the chamber of 1.3×10⁻³ Pa or less. The sputtering target included a pure aluminum sputtering target having a diameter of 100 mm and a thickness of 5 mm and, affixed thereon, chips of a desired metal element (metal element to be added). For the deposition of a pure aluminum film, a pure aluminum sputtering target alone was used as the sputtering target.

Next, Ar gas was fed into the chamber, and the pressure in the chamber was controlled to 2.6×10⁻¹ Pa. Sputtering was then performed while applying a power of 260 W to the sputtering target from a direct-current (DC) power source to deposit an aluminum alloy film having a desired composition on the entire surface of the substrate. Thus, a series of specimens was obtained.

In this process, the aluminum alloy films were controlled to have different compositions by changing the type of metal element and number of the chips to be arranged on the pure aluminum sputtering target, whereas the film thickness was controlled to be 150 nm by regulating the deposition time.

The aluminum alloy film specimens prepared by sputtering were each subjected to a compositional analysis, a reflectance measurement, and a roughness measurement and were subjected to a moisture resistance test and an alkali resistance test-1 to evaluate durability, according to the following methods.

<Compositional Analysis>

The chemical composition of each aluminum alloy film specimen was measured through inductively coupled plasma (ICP) emission spectrometry. Specifically, the specimen was dissolved in an acid capable of dissolving the aluminum alloy film to give a solution, and the ratio between Al and an added element in the solution was measured through ICP emission spectrometry, and the measured ratio was standardized to 100% and defined as the composition (in units of atomic percent) of the aluminum alloy film.

<Measurement of Visible-light Reflectance>

The reflectance of each specimen deposited on the glass substrate was measured at wavelengths of from 250 nm to 800 nm, and based on this, a visible-light reflectance was calculated in accordance with Japanese Industrial Standards (JIS) 3106.

<Measurement of Roughness>

Each of the specimens deposited on the glass substrate was subjected to roughness measurements. The roughness was determined by observing the surface profile of the specimen with an atomic force microscope, and calculating an average roughness (arithmetic average roughness) Ra as the roughness from the observation.

<Moisture Resistance Test>

Each of the specimens was held in a furnace maintained at a temperature of 55° C. and relative humidity of 95% for 240 hours and retrieved from the furnace. The specimen was then subjected to an optical transmission test, in which the specimen was placed in an environment at an interior illuminance of 320 lux under a fluorescent lamp, held to the fluorescent lamp so that the reflective film of the reflective film laminate faced the fluorescent lamp, and whether light transmitted or not was visually observed. Specimen showing no light transmission after the moisture resistance test were evaluated as “∘”, whereas specimens showing light transmission were evaluated as “x”. Then, specimens evaluated as “∘” were estimated to be accepted.

<Alkali Resistance Test-1>

Each of the specimens was immersed in a 1 percent by mass KOH aqueous solution for 10 minutes, rinsed with water, dried, placed in an environment at an interior illuminance of 320 lux under a fluorescent lamp, held to the fluorescent lamp so that the reflective film of the reflective film laminate faced the fluorescent lamp, and whether light transmitted or not was visually observed. In addition, whether the film discolored or not under the above conditions was visually observed. Specimens showing no light transmission after the alkali resistance test-1 were evaluated as “∘”; specimens partially showing light transition were evaluated as “Δ”; and specimens each becoming transparent substantially its entirety were evaluated as “x”. Independently, specimens showing no film discoloring were evaluated as “∘”; and specimen showing film discoloration were evaluated as “x”. Specimens evaluated as “∘” both in light transmission and film discoloration were estimated to be accepted.

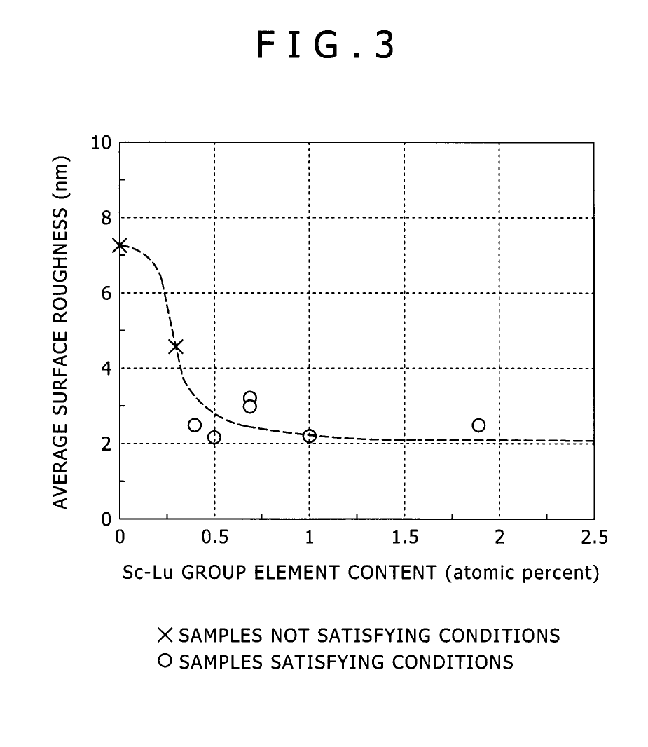

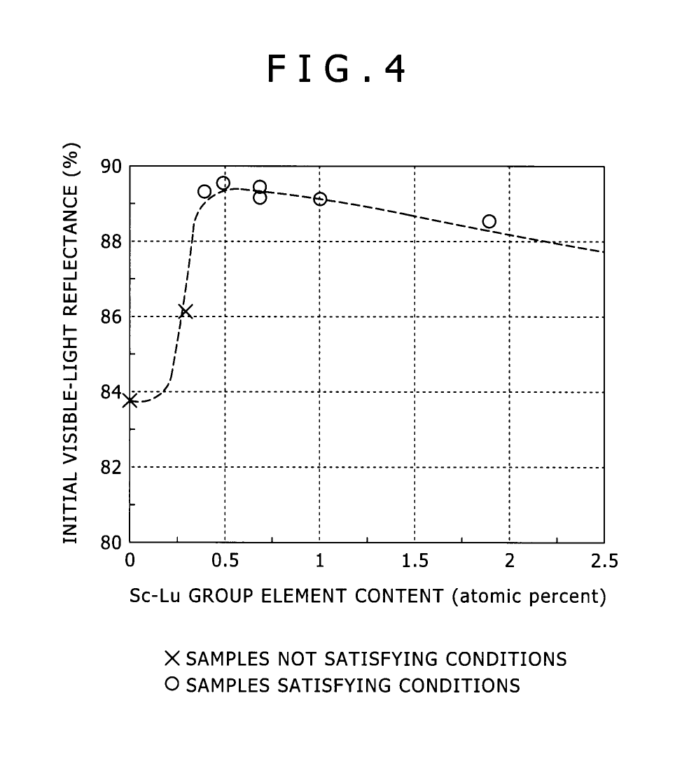

The results of the measurements and the alkali resistance test-1 are shown in Table 1. Specifically, Table 1 shows, of each specimen, film composition, rare-earth element content, initial visible-light reflectance, and average roughness; and, of the reflective film of each reflective film laminate, the results of the moisture resistance test and alkali resistance test. FIG. 3 shows how the average roughness as measured with the atomic force microscope varies depending on the content of Sc—Lu group element. FIG. 4 shows how the initial visible-light reflectance varies depending on the content of Sc—Lu group element. In FIGS. 3 and 4, the symbol “x” represents data of a sample not satisfying the conditions according to First Embodiment of the present invention; and the symbol “∘” represents data of a sample satisfying the conditions according to First Embodiment of the present invention.

FIGS. 3 and 4 demonstrate as follows. Samples not satisfying the conditions according to First Embodiment of the present invention each had a film surface average roughness of more than 4 nm as measured with an atomic force microscope and had a low initial visible-light reflectance of less than 88%. In contrast, samples satisfying the conditions according to First Embodiment of the present invention each had a film surface average roughness of 4 nm or less as measured with an atomic force microscope and had an initial visible-light reflectance of 88 or more.

Table 1 demonstrates as follows. The reflective film according to Comparative Example 1-1 had a reflectance of less than the theoretical reflectance of 88%, because this film was a pure aluminum film and had a rough surface when deposited by sputtering. After the alkali resistance test-1, almost the entire film was dissolved and became transparent.

When an alloy metal, even being one of the Sc—Lu group elements (Sc, Y, La, Gd, Tb, and Lu), was added in an amount of less than 0.4 atomic percent as in Comparative Example 1-2, the resulting film had a rough surface and had a reflectance of less than 88%, because the alloy metal did not effectively help to form fine aluminum grains. The resulting film also showed insufficient alkali resistance and showed partial light transmission after the alkali resistance test-1.

The aluminum alloy film according to Comparative Example 1-3 had a reflectance of less than 88%, because an alloy metal, even being one of the Sc—Lu group elements, was added in an amount of more than 2.5 atomic percent.

Comparative Example 1-4 had a content of Sc—Lu group element within the range specified in the present invention, but had an average roughness of more than 4 nm, and thereby had an initial reflectance of less than 88%. This is probably because the deposition was performed at a power of 500 W and a distance between the substrate and the target of 45 mm, thereby the sputtered particles had increased energy to reduce the nucleation density.

Comparative Example 1-5 did not satisfy the conditions according to First Embodiment of the present invention, employed, as an alloy element, such a rare-earth element as to cause the Al film to discolor in an alkali resistance test, and showed discoloration over substantially the entire film after the alkali resistance test-1, although showing no light transmission.

The aluminum alloy film according to Comparative Example 1-6 employed Mg as an alloy element, became transparent as a result of the moisture resistance test, showed light transmission after the moisture resistance test, and was dissolved almost entirely and became transparent after the alkali resistance test-1.

The aluminum alloy film according to Comparative Example 1-7 did not satisfy the conditions according to First Embodiment of the present invention, employed, as an alloy element, a rare-earth element not effectively improving the alkali resistance, and was dissolved almost entirely and became transparent after the alkali resistance test-1.

The aluminum alloy films according to Examples 1-1 to 1-10 as working examples of the present invention satisfied the conditions according to First Embodiment of the present invention, had high durability, and neither became transparent nor were discolored even after the moisture resistance test and the alkali resistance test-1.

### Example 2 and Comparative Example 2

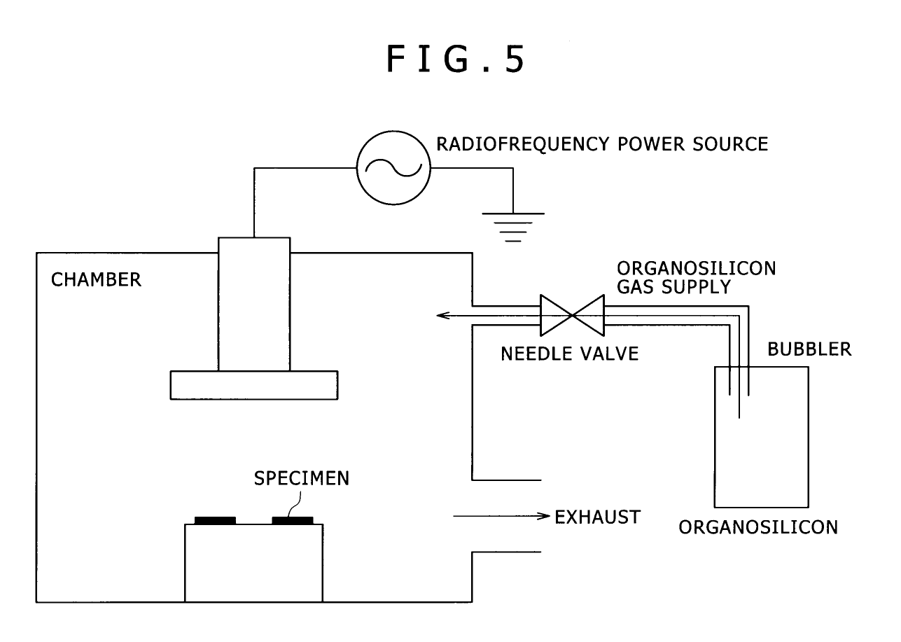

Specimens of aluminum alloy films as with Example 1 were prepared by the procedure of Example 1, and using them, reflective film laminates were prepared. The way to prepare the laminates will be described in detail below. Each of the specimens obtained by the deposition was placed in a chamber of a plasma CVD apparatus as illustrated in FIG. 5, and the chamber was evacuated to a pressure of 1.3×10⁻³ Pa or less. Next, a needle valve between a bubbler and the chamber in the apparatus was opened to introduce vapor of an organosilicon from the bubbler into the chamber, and the inner pressure of the chamber was set to 1.3 Pa by regulating the degree of opening of the needle valve. A radiofrequency power (RF; high-frequency power) was then applied to an upper electrode in the chamber to generate plasma at a power of 200 W to thereby form a plasma-enhanced polymerized film 40 nm thick on the specimen. Thus, a series of reflective film laminates was obtained. The organosilicon used herein was hexamethyldisiloxane.

The resulting reflective film laminates were each subjected to an alkali resistance test-2, and an acid resistance test. These tests were performed according to the following methods.

<Alkali Resistance Test-2>

Each of the reflective film laminates was immersed in a 1 percent by mass KOH aqueous solution for 60 minutes, rinsed with water, dried, placed in an environment at an interior illuminance of 320 lux under a fluorescent lamp, held to the fluorescent lamp so that the reflective film of the reflective film laminate faced the fluorescent lamp, and whether light transmitted or not was visually observed. In addition, whether the film discolored or not under the above conditions was visually observed. Samples showing no light transmission after the alkali resistance test-2 were evaluated as “∘”; and samples showing light transition were evaluated as “x”. Independently, samples showing no film discoloring were evaluated as “∘”; and samples showing film discoloration were evaluated as “x”. Samples evaluated as “∘” both in light transmission and film discoloration were estimated to be accepted.

<Acid Resistance Test>

Each of the reflective film laminates was immersed in a 1 percent by mass H₂SO₄ aqueous solution for 30 minutes, rinsed with water, dried, placed in an environment at an interior illuminance of 320 lux under a fluorescent lamp, held to the fluorescent lamp so that the reflective film of the reflective film laminate faced the fluorescent lamp, and whether light transmitted or not was visa tally observed. In addition, whether the film discolored or not under the above conditions was visually observed. Samples showing no light transmission after the acid resistance test were evaluated as “∘”; and samples showing light transition were evaluated as “x”. Samples evaluated as “0” were estimated to be accepted.

The results of the alkali resistance test-2 and the acid resistance test are shown in Table 2. The reflective film laminates according to Comparative Examples 2-1, 2-6, and 2-7 each included an aluminum alloy film not satisfying the conditions according to First Embodiment of the present invention and showed light transmission after the alkali resistance test-2, even though a plasma-enhanced polymerized film as a protective coating was formed on the aluminum alloy film. This is probably because the protective coating had pinholes, and the pinhole areas served as origins of and caused corrosion of the aluminum alloy film.

The reflective film laminate according to Comparative Example 2-5 included an aluminum alloy film not satisfying the conditions according to First Embodiment of the present invention and employing, as an alloy element, such a rare-earth element as to cause the Al film to discolor after an alkali resistance test, and thereby showed partial discoloration on the film surface after the alkali resistance test-2, although showing no light transmission.

In contrast, the reflective film laminates according to Examples 2-1 to 2-10 as working examples of the present invention showed neither light transmission nor film discoloration even after the very stringent alkali resistance test-2, because the constitutive aluminum alloy film itself had high durability, and a protective coating was further formed thereon. In addition, they showed no light transmission after the acid resistance test. The reflective film laminates are therefore advantageously usable as reflective films, because they less suffer from film deterioration and reduction in reflectance even when the protective coating provided thereon bears pinholes.

### Example 3 and Comparative Example 3

Some working examples of sputtering targets for the deposition of aluminum alloy films will be illustrated below.

Al—Y alloy, Al—La alloy, and Al—Gd alloy sputtering targets each having a diameter of 100 mm and a thickness of 5 mm and having different compositions were prepared by spray forming. Using the sputtering targets, a series of aluminum alloy films 150 nm thick was formed on a glass substrate by the same procedure using the same apparatus as with Examples 1 and 2 and thereby yielded specimens. The resulting aluminum alloy film specimens were subjected to the compositional analysis to measure alloy compositions of the films and subjected to the visible-light reflectance measurement to determine the visible-light reflectances of the aluminum alloy film specimens.

Table 3 shows the measured chemical compositions of the aluminum alloy targets used, and the measured chemical compositions and visible-light reflectances of the aluminum alloy films.

The aluminum alloy sputtering targets according to Comparative Examples 3-1 and 3-2 had chemical compositions with rare-earth element contents higher than that specified in the present invention, thereby gave aluminum alloy films which had high rare-earth element contents and had initial visible-light reflectances of less than 88%.

In contrast, the aluminum alloy sputtering targets according to Examples 3-1 to 3-5 as working examples of the present invention had chemical compositions each within the range specified in the present invention, thereby gave, through deposition, aluminum alloy films which had chemical compositions within the range specified in the present invention and had high visible-light reflectances of 88% or more. These demonstrate that aluminum alloy sputtering targets, when having chemical compositions controlled within the range specified in the present invention, can form aluminum alloy films having high visible-light reflectances of 88% or more.

TABLE 1

| | | Initial | | | | | Category |
|---|---|---|---|---|---|---|---|
| | Alloy element | visible-light | Average | | | | (Examples and |
| Film | content | reflectance | roughness | | Alkali resistance test-1 | | Comparative |
| composition | (atomic %) | (%) | (nm) | Moisture resistance | Light transmission | Film discoloration | Examples) |
| Al—Sc | 0.4 | 89.3 | 2.2 | no light transmission (∘) | no transmission (∘) | no discoloration (∘) | Example 1-1 |
| Al—Y | 0.5 | 89.4 | 2.3 | no light transmission (∘) | no transmission (∘) | no discoloration (∘) | Example 1-2 |
| Al—Y | 1 | 89.0 | 2.4 | no light transmission (∘) | no transmission (∘) | no discoloration (∘) | Example 1-3 |
| Al—La | 0.5 | 89.5 | 1.8 | no light transmission (∘) | no transmission (∘) | no discoloration (∘) | Example 1-4 |
| Al—La | 0.7 | 89.1 | 3.2 | no light transmission (∘) | no transmission (∘) | no discoloration (∘) | Example 1-5 |
| Al—La | 1.9 | 88.5 | 3.2 | no light transmission (∘) | no transmission (∘) | no discoloration (∘) | Example 1-6 |
| Al—Gd | 0.7 | 89.5 | 3.1 | no light transmission (∘) | no transmission (∘) | no discoloration (∘) | Example 1-7 |
| Al—Gd | 2 | 88.2 | 2.2 | no light transmission (∘) | no transmission (∘) | no discoloration (∘) | Example 1-8 |
| Al—Tb | 1 | 89.0 | 2.0 | no light transmission (∘) | no transmission (∘) | no discoloration (∘) | Example 1-9 |
| Al—Lu | 0.9 | 89.2 | 1.9 | no light transmission (∘)) | no transmission (∘) | no discoloration (∘) | Example 1-10 |
| Al | none | 83.8 | 7.3 | no light transmission (∘) | becoming transparent (x) | — | Com. Ex. 1-1 |
| Al—La | 0.3 | 86.1 | 4.6 | no light transmission (∘) | partial transmission (Δ) | no discoloration (∘) | Com. Ex. 1-2 |
| Al—La | 3 | 87.0 | 3.0 | no light transmission (∘) | no transmission (∘) | no discoloration (∘) | Com. Ex. 1-3 |
| Al—Gd | 2 | 84.6 | 4.9 | no light transmission (∘) | no transmission (∘) | no discoloration (∘) | Com. Ex. 1-4 |
| Al—Nd | 1.7 | 88.6 | 2.3 | no light transmission (∘) | no transmission (∘) | discoloration (x) | Com. Ex. 1-5 |
| Al—Mg | 2.1 | 89.1 | 2.9 | light transmission (x) | becoming transparent (x) | — | Com. Ex. 1-6 |
| Al—Eu | 2 | 88.5 | 2.9 | no light transmission (∘) | becoming transparent (x) | — | Com. Ex. 1-7 |

TABLE 2

| | Alloy | | | Thickness of | | | | Category |
|---|---|---|---|---|---|---|---|---|
| | element | Initial | | plasma- | | | | (Examples |
| | content | visible-light | Average | enhanced | | | | and |
| Film | (atomic | reflectance | roughness | polymerized | Alkali resistance test-2 | | | Comparative |
| composition | %) | (%) | (nm) | film (nm) | Light transmission | Film discoloration | Acid resistance test | Examples) |
| Al—Sc | 0.4 | 89.3 | 2.2 | 40 | no transmission (∘) | no discoloration (∘) | no light transmission (∘) | Example 2-1 |
| Al—Y | 0.5 | 89.4 | 2.3 | 40 | no transmission (∘) | no discoloration (∘) | no light transmission (∘) | Example 2-2 |
| Al—Y | 1 | 89.0 | 2.4 | 40 | no transmission (∘) | no discoloration (∘) | no light transmission (∘) | Example 2-3 |
| Al—La | 0.5 | 89.5 | 1.8 | 40 | no transmission (∘) | no discoloration (∘) | no light transmission (∘) | Example 2-4 |
| Al—La | 0.7 | 89.1 | 3.2 | 40 | no transmission (∘) | no discoloration (∘) | no light transmission (∘) | Example 2-5 |
| Al—La | 1.9 | 88.5 | 3.2 | 40 | no transmission (∘) | no discoloration (∘) | no light transmission (∘) | Example 2-6 |
| Al—Gd | 0.7 | 89.5 | 3.1 | 40 | no transmission (∘) | no discoloration (∘) | no light transmission (∘) | Example 2-7 |
| Al—Gd | 2 | 88.2 | 2.2 | 40 | no transmission (∘) | no discoloration (∘) | no light transmission (∘) | Example 2-8 |
| Al—Tb | 1 | 89.0 | 2.0 | 40 | no transmission (∘) | no discoloration (∘) | no light transmission (∘) | Example 2-9 |
| Al—Lu | 0.9 | 89.2 | 1.9 | 40 | no transmission (∘) | no discoloration (∘) | no light transmission (∘) | Example 2-10 |
| Al | none | 83.8 | 7.3 | 40 | transmission (x) | no discoloration (∘) | no light transmission (∘) | Com. Ex. 2-1 |
| Al—La | 0.3 | 86.1 | 4.6 | 40 | transmission (x) | no discoloration (∘) | no light transmission (∘) | Com. Ex. 2-2 |
| Al—La | 3 | 87.0 | 3.0 | 40 | no transmission (∘) | no discoloration (∘) | no light transmission (∘) | Com. Ex. 2-3 |
| Al—Gd | 2 | 84.6 | 4.9 | 40 | no transmission (∘) | no discoloration (∘) | no light transmission (∘) | Com. Ex. 2-4 |
| Al—Nd | 1.7 | 88.6 | 2.3 | 40 | no transmission (∘) | discoloration (x) | no light transmission (∘) | Com. Ex. 2-5 |
| Al—Mg | 2.1 | 89.1 | 2.9 | 40 | transmission (x) | no discoloration (∘) | no light transmission (∘) | Com. Ex. 2-6 |
| Al—Eu | 2 | 88.5 | 2.9 | 40 | transmission (x) | no discoloration (∘) | no light transmission (∘) | Com. Ex. 2-7 |

TABLE 3

| Aluminum alloy sputtering target | | Content of rare-earth | | Category (Examples |
|---|---|---|---|---|
| | Content of rare-earth | element in aluminum | Initial visible-light | and Comparative |
| Composition | element (atomic %) | alloy film (atomic %) | reflectance (%) | Examples) |
| Al—Y | 0.5 | 0.4 | 89.5 | Example 3-1 |
| Al—Y | 1 | 0.9 | 89.0 | Example 3-2 |
| Al—Gd | 1.5 | 1.2 | 89.2 | Example 3-3 |
| Al—Gd | 2.5 | 1.5 | 88.6 | Example 3-4 |
| Al—La | 2.5 | 1.5 | 88.3 | Example 3-5 |
| Al—Gd | 5 | 4 | 87.2 | Com. Ex. 3-1 |
| Al—La | 4.8 | 2.9 | 87.1 | Com. Ex. 3-2 |

While the present invention has been described in detail with reference to the specific embodiments thereof it is obvious to those skilled in the art that various changes and modifications can be made in the invention without departing from the spirit and scope of the invention. The present application is based on Japanese Patent Application No. 2009-142389 filed on Jun. 15, 2009 and Japanese Patent Application No. 2010-134874 filed on Jun. 14, 2010, the entire contents of which are incorporated herein by reference.

### INDUSTRIAL APPLICABILITY

The aluminum alloy reflective films according to the present invention less suffer from reduction in reflectance and have high reflectances even when deposited by sputtering. In addition, the aluminum alloy reflective films excel in alkali resistance (resistance to corrosion by alkalis), acid resistance (resistance to corrosion by acids), and moisture resistance (resistance to a hot and humid environment), are thereby resistant to reduction in reflectance even when a protective coating provided thereon has defects, and are advantageously usable as reflective films with improved durability, thus being useful.

1. An aluminum alloy reflective film which comprises at least one element selected from the group consisting of Sc, Y, La, Gd, Tb, and Lu in a total content of from 0.4 to 2.5 atomic percent, with the remainder being Al and inevitable impurities, and which has an average roughness Ra of film surface of 4 nm or less as measured with an atomic force microscope.

2. An automotive lighting device comprising the aluminum alloy reflective film of claim 1 as a reflective film.

3. An illumination device comprising the aluminum alloy reflective film of claim 1 as a reflective film.

4. A reflective film laminate comprising the aluminum alloy reflective film of claim 1 and, present thereon, a plasma-enhanced polymerized film.

5. An automotive lighting device comprising the reflective film laminate of claim 4 as a reflective film laminate.

6. An illumination device comprising the reflective film laminate of claim 4 as a reflective film laminate.

7. An aluminum alloy sputtering target for the formation of the aluminum alloy reflective film of claim 1, the sputtering target comprising at least one element selected from the group consisting of Sc, Y, La, Gd, Tb, and Lu in a total content of from 0.4 to 4.5 atomic percent, with the remainder being Al and inevitable impurities.

8. The aluminum alloy sputtering target according to claim 7, which has been prepared by spray forming.
